(19) United States
(12) Patent Application Publication
(10) Pub. No.: US 2018/0096975 A1
(43) Pub. Date: Apr. 5, 2018

(54) HIGH DENSITY PACKAGE ON PACKAGE DEVICES CREATED THROUGH A SELF ASSEMBLY MONOLAYER ASSISTED LASER DIRECT STRUCTURING PROCESS ON MOLD COMPOUND

(71) Applicant: Intel Corporation, Santa Clara, CA (US)

(72) Inventors: Fay Hua, Fremont, CA (US); Robert L. Sankman, Phoenix, AZ (US)

(21) Appl. No.: 15/282,473

(22) Filed: Sep. 30, 2016

(51) Int. Cl. H01L 25/10; H01L 23/29; H01L 23/498; H01L 21/48; H01L 25/00; H01L 23/00

(52) U.S. Cl. CPC H01L 25/105; H01L 2224/02315; H01L 23/49827; H01L 21/4853; H01L 25/50; H01L 24/02; H01L 24/04; H01L 2225/1035; H01L 2225/1041; H01L 2225/1058; H01L 2225/107; H01L 2224/0237; H01L 2224/0239; H01L 2924/01029; H01L 2224/04105; H01L 23/295

(57) ABSTRACT

A high density package on package electrical device is disclosed. The electrical device comprises a first integrated circuit package comprising a substrate, an integrated circuit component attached to the substrate, and a molding compound covering the component, wherein the top of the molding compound has a redistribution layer of metal covering at least part of the molding compound. The device further comprises a second integrated circuit package including a second substrate, a semiconductor component attached to the substrate, and a molding compound covering the electronic component, wherein the bottom of the substrate includes metal contacts for communication between the second integrated circuit package and other components. The device further comprises a solder layer that connects the top of the first integrated circuit package to the bottom of the second electric package by connecting the metal of the redistribution layer to the metal connections on the bottom of the second substrate.

### TECHNICAL FIELD

Embodiments described herein generally relate to electrical interconnections in micro electrical devices.

### BACKGROUND

Electronic devices have grown increasingly small and power efficient. As such, each component within an electronic device (e.g., a smart phone, laptop, tablet, or other size dependent device) needs to be developed in smaller sizes but not suffer any reduction in operability. In an effort to decrease the size of various electric components, a variety of strategies have been used. Thus, any strategy that enables further reduction in size is important.

For example, solid state drives (SSDs) have been developed in smaller form factors for use in ultrabooks, tablets, 2 in 1s, and so on. The standard 1.8 inch and 2.5 inch form factors were developed to meet the need for smaller form factors. More recently, caseless form factors have been developed. To maintain small form factors, chips can be stacked package on package (POP) to reduce total area. Such dense packaging results in a need for better and more reliable communication.

### BRIEF DESCRIPTION OF THE DRAWINGS

FIG. 1 depicts an integrated circuit device package, in accordance with some example embodiments.

FIG. 2 depicts an integrated circuit device package, in accordance with some example embodiments.

FIG. 3 is a flow diagram illustrating a method, in accordance with some example embodiments, for selectively metallizing the mold compound surface using a laser direct structuring process that uses self-assembling monolayer.

FIGS. 4A-4D depict an integrated circuit device package 400 in accordance with some example embodiments as it undergoes the process to use a SAM assisted Laser direct structuring process on the top of the mold compound.

FIG. 5 depicts two integrated circuit devices arranged in a package-on-package arrangement, in accordance with some example embodiments.

FIG. 6 shows a flow diagram of a method of creating a package-on-package device using a laser assisted self-activating monolayer, in accordance with some example embodiments.

FIG. 7 is block diagram of an electronic system, in accordance with some example embodiments.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

As electronic components grow smaller, the space available to establish communications between them is reduced. At the same time, the desired volume and speed of communication is increased. As such, the need to facilitate communication between components is increased. In some example embodiments, an integrated circuit is contained within a package (a supporting structure that shields the circuit from physical damage and corrosion using a molding compound). Metal pads, which enable communication, are typically very expensive and difficult to place directly over the die containing the integrated circuit.

Indeed, when placing metal contacts (pads) on top of mold compound on the first package, through mold via technology can only allow metal contacts to be formed at peripheral area of the molding compound (e.g., where the molding is not directly over the substrate circuitry. Thus, there is only a very limited area can be used to form interconnect pads with this technology. If more interconnect pads are needed, the pads will be very small, which can impose reliability issues Thus, the total area on the package that can be used to facilitate communication between components is very small.

To add metal contacts to the entire top of the molding compound using traditional lithographic processes would be very expensive. In order to produce this effect in a cost effective way, a self-assembling monolayer is used. In this way, connections (pads) can be added at any point on the package that is desired.

To create a self-assembling mono-layer, the molding is first activated in a specific pattern using a pulsed-wave ultraviolet laser. The activated area is then modified by making the area rich in hydroxyl moieties (e.g., a hydrolysis process like exposing to water).

In some example embodiments, the pattern that is now rich in OH is then soaked with the self-assembling mono-layer. The self-assembling mono-layer (SAM) used is siloxane with specific function group. One end of the SAM is easy to condense with —OH to form strong bond with the mold compound material, the other end of SAM has reactive function group, including, but not limited to, NH2, —SH, Pyridill, and so on for fixing the palladium (Pd) catalyst atoms that will act as nucleation points for copper deposition during e-less plating process. Other example functional groups include but are not limited to an amine moiety, a sulfhydryl moiety and a pyridil moiety for reacting with a palladium (Pd) catalyst.

Once the self-assembling mono-layer is in place, the modified self-assembled monolayer is exposed to a bath with an ionic form of the metal (e.g., nickel ion, copper ion, etc.) and a reducing agent such as an amine, a borane or a hypophosphite. This allows metallization along the pattern activated by the laser.

In this way, a pattern of metal can be created on top of the molding of nearly any package. A connection between the top pattern and the bottom of another package allows the packages to be stacked in a package on package (PoP) configuration while still allowing high bandwidth and reliability between the two packages.

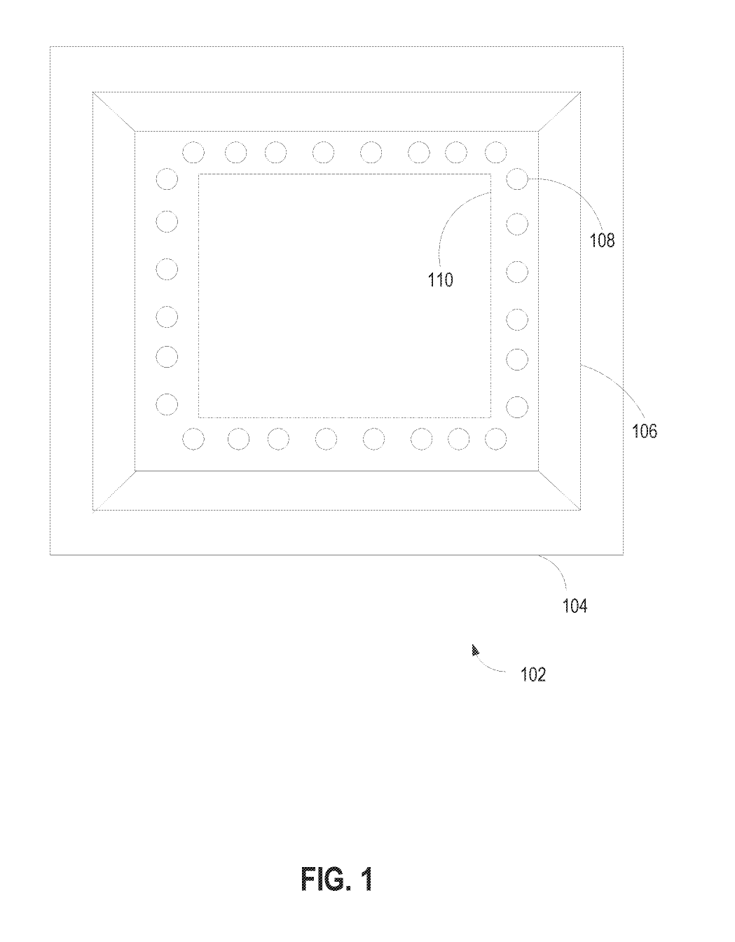

FIG. 1 depicts an integrated circuit device package 102 in accordance with some example embodiments. In this depiction there is a substrate 104 and a molding compound 106 affixed to the substrate 104. The substrate 104 has a series of through mold vias that allow metal components to protrude from the substrate 104 up through the molding compound 106.

In some example embodiments, the molding compound 106 is composed of polymeric compounds. In addition, generally the substrate 104 will include further communicative components (e.g., metal contacts) that allow the integrated circuit component that is attached to the substrate 104 and covered by the molding 106 to communicate through the pins 108.

In this example, metal contacts 108 are only available in areas of the molding 106 not directly above the integrated circuit component. The area of the integrated circuit component is shown by dashed line 110. As can be seen, a significant part of the top of the package 102 is unable to be used with this method.

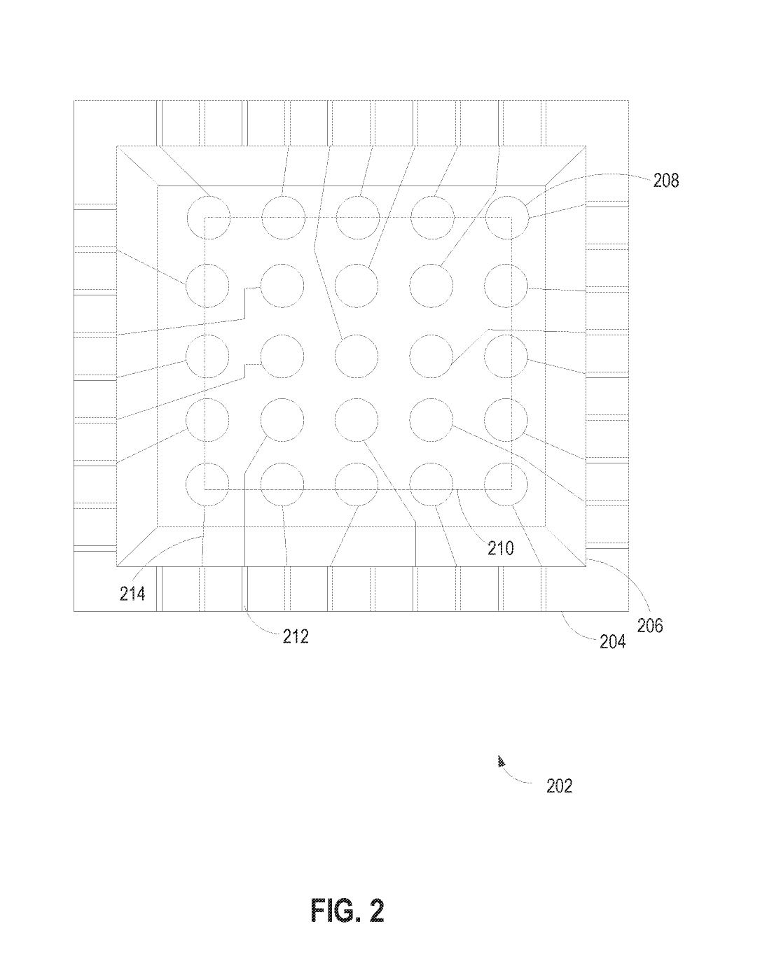

FIG. 2 depicts an integrated circuit device package 202, in accordance with some example embodiments. In this depiction there is a substrate 204 and a molding compound 206 affixed to the substrate 204. The substrate 204 has a number of metal lead connections (212 is labelled as an example) attached to it. In some example embodiments, the molding compound 206 covers or otherwise obscures addition communication components that allow the integrated circuit component to communicate with other components.

By using the self-assembling monolayer assisted laser directed structuring process, the top of the molding compound 206 is now able to have metal connections 208 placed anywhere on the surface. For example, the outline 210 represents the position of the integrated circuit under molding compound 206. The self-assembling monolayer process allows metal connections 208 in patterns that can cover all (or nearly all) of the molding area. This allows for much higher bandwidth of communication as well as larger and more reliable metal contacts 108.

In some example embodiments, each metal connection pad 208 is connect (via a wire bond or other connection ability) to a metal lead connection of the substrate 204. In this way, a component that connects electrically/communicatively with the metal connections 208 can share information and/or commands with the integrated circuit component.

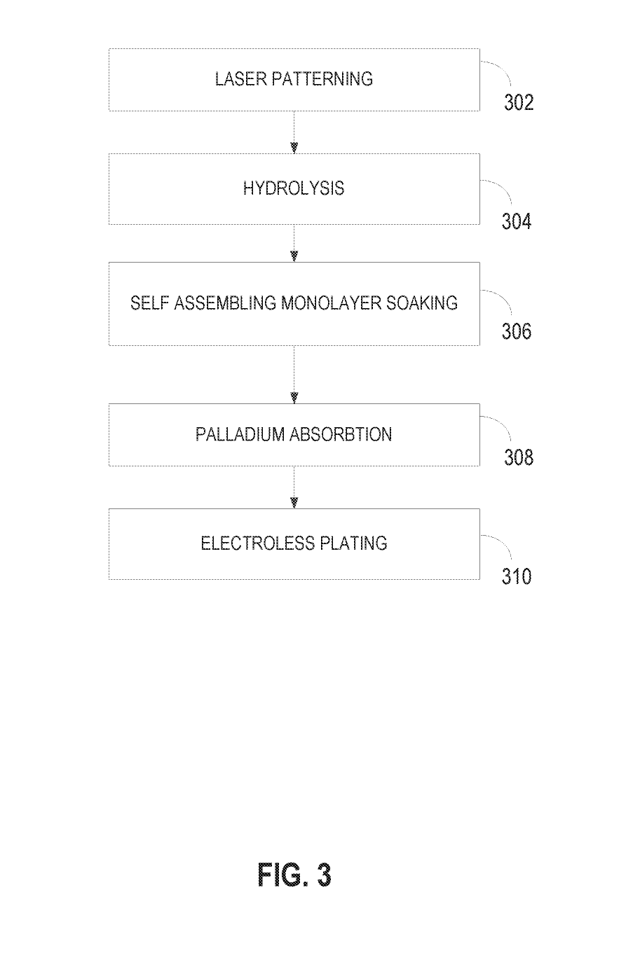

FIG. 3 is a flow diagram illustrating a method, in accordance with some example embodiments, for selectively metallizing the mold compound surface using a laser direct structuring process that uses self-assembling monolayer but not the normal litho-resist process. The method described can also be performed by any suitable configuration of hardware.

In some example embodiments, a pulsed wave ultraviolet laser is used to activate a pattern (302) on the mold compound surface. The laser uses pulse waves to activate the area of the molding compound by breaking chemical bonds in the polymer compound that makes up the molding 106.

Once the laser has activated the desired pattern, the activated area of a polymer layer is modified by making the area rich in hydroxyl (—OH) during hydrolysis (304). For example, the molding 106 may be exposed to water such as by placing the substrate 204 in a tank of water to allow hydroxyl moieties to react or otherwise bond with the active area.

In some example embodiments, a self-assembling monolayer is formed by condensation (306). In some example embodiments, the monolayer includes a functional group, X, that is suitable for fixing Pd atoms that will act at uncleation points for copper deposition during e-less plating process. Representative functional groups include but are not limited to an amine moiety, a sulfhydryl moiety and a pyridil moiety for reacting with a palladium (Pd) catalyst.

In some example embodiments, palladium ions are introduced to during the catalyst process, and the palladium atoms are act as uncleation points for copper atom deposition (308). The palladium ions react with the SAM as a catalyst. Through this process the palladium ions attach to the functional groups of the self-assembled monolayer.

The self-assembling monolayer is then reacted with a conductive material (e.g., copper). For example, the substrate 204 is placed in a bath with an ionic form of a metal. The palladium acts as a catalyst for a reduction of metal ions in the bath into a metallic form. In this way, conductive lines of metal are formed on the molding 106 compound uses an electrolysis process.

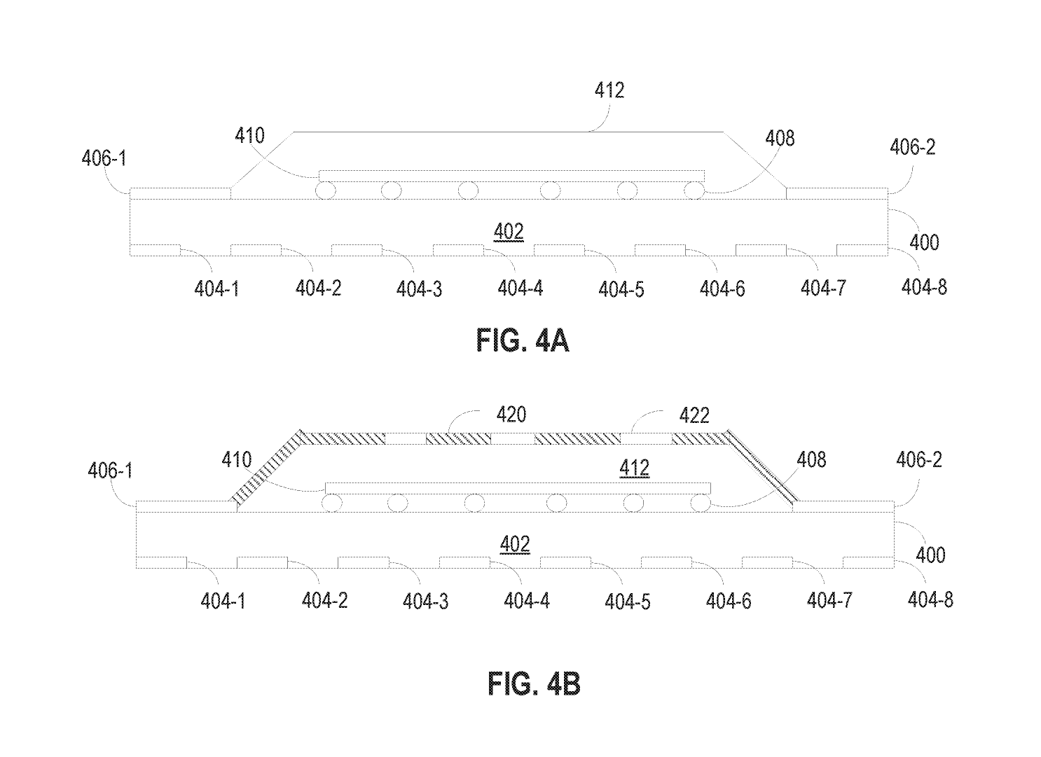

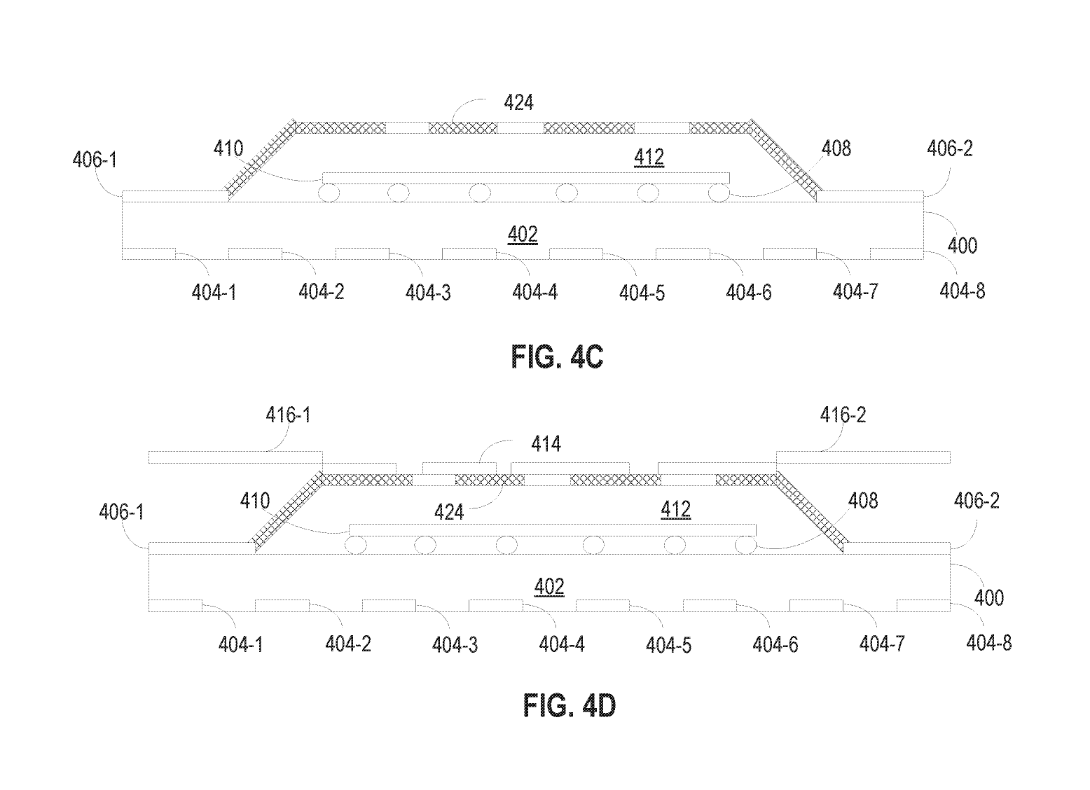

FIGS. 4A-4D depict an integrated circuit device package 400 in accordance with some example embodiments as it undergoes the process to use a self-assembling monolayer assisted laser direct structuring process on the top of the mold compound.

The integrated circuit device package 400 includes a substrate 402. The substrate 402 includes a series of metal or metallic communication connections 404-1 to 404-8 at the bottom of the substrate 402. These connections allow the integrated circuit device package 400 to communicate to other components by attaching a communication line to one of these connections 404-1 to 404-8.

Similarly, the integrated circuit device package 400 includes one or more communication pads attached to the top of the pads 406-1 to 406-2. In some example embodiments, these pads 406-1 to 406-2 are attached to the substrate 402 by a surface mount technology.

In some example embodiments, an integrated circuit component 410 (e.g., a die containing a processing component) is attached to the substrate 402. In this example, the integrated circuit component 410 is attached to the substrate 402.

In some example embodiments, the connection between the integrated circuit component 410 and the substrate 402 using solder. In this example, a ball grid array 408 is used to connect integrated circuit component 410 and the substrate 402, but other connection methods are possible.

The integrated circuit component 410 is covered with a molding compound 412. In some example embodiments, the molding compound 412 is a polymeric material and products the integrated circuit component 410 from damage and degradation.

In FIG. 4B a laser has been used to activate selected portions of the molding 106. As can be seen, some sections of the top (and side) of the molding compound 412 have been activated 420 while other sections 422 have not been activated.

The integrated circuit device package 400 also includes a substrate 402, a series of metal or metallic communication connections 404-1 to 404-8, one or more communication pads attached to the top of the pads 406-1 to 406-2, an integrated circuit component 410, a ball grid array 408 that connects the integrated circuit component 410 to the substrate 402, and a molding compound 412.

FIG. 4C depicts the integrated circuit device package 400 after metal traces 424 have been applied by the electrolysis process. As can be seen, the metal trace 424 covers the top of the molding compound 412. The metal trace 424 also attaches to the metal of leads 406-1 to 406-2 attached to the substrate 402.

The integrated circuit device package 400 also includes a substrate 402, a series of metal or metallic communication connections 404-1 to 404-8, one or more communication pads attached to the top of the pads 406-1 to 406-2, an integrated circuit component 410, a ball grid array 408 that connects the integrated circuit component 410 to the substrate 402, and a molding compound 412.

In this way, the integrated circuit component 410 is able to receive and deliver communication through the top of the molding 106.

In FIG. 4D a solder resist layer 414 is added to the top of the metal trace layer that was plated on the mold compound. The solder resist protects the metal trace (e.g., copper) pattern, with openings present only where a second package would be soldered to the first package

The integrated circuit device package 400 includes a substrate 402, a series of metal or metallic communication connections 404-1 to 404-8, one or more communication pads attached to the top of the pads 406-1 to 406-2, an integrated circuit component 410, a ball grid array 408 that connects the integrated circuit component 410 to the substrate 402, and a molding compound 412.

In some example embodiments, the solder resist layer 414 is printed onto the top of the metal trace layer 424 using a stencil printing method. A solder resist stencil 416-1 to 416-2 is used to ensure that the solder resist layer 414 is applied only where needed.

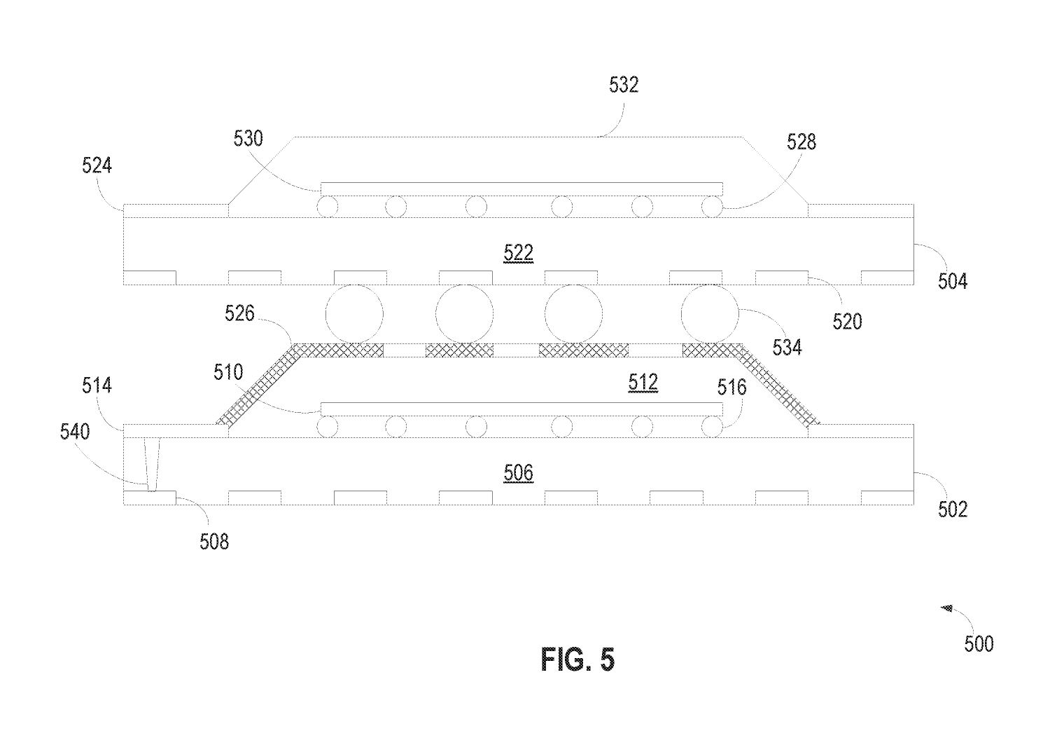

FIG. 5 depicts two integrated circuit devices arranged in a package-on-package arrangement, in accordance with some example embodiments.

Both the first integrated circuit package 502 and the second integrated circuit device package 504 include a substrate 506 and 522, have a series of connection points on the bottom of the substrate 508 and 520, have connection points on the top of the substrate 514 and 524, an integrated circuit component 510 and 530 connected to their respective substrates 506 and 522 via solder 516 and 528.

Each integrated circuit package 502 and 504 has a molding compound 512 and 532 that covers and protects the integrated circuit components 510 and 530.

The first integrated circuit package 502 has a pattern of metal 526 layered over the top of the molding compound 512. In this way, the first integrated circuit package 502 is connected to the second integrated circuit package 504 through a ball grid array 534 that connects the metal contacts 520 at the bottom of the second integrated circuit package 504 to the top metal traces 526 of the first integrated circuit package 502.

In this example, the metal traces 526 one the second integrated circuit package 504 is connected to metal contacts 528 on the bottom of the second integrated circuit 504 using a through mold via 540. In other example embodiments, a wire bond may be used.

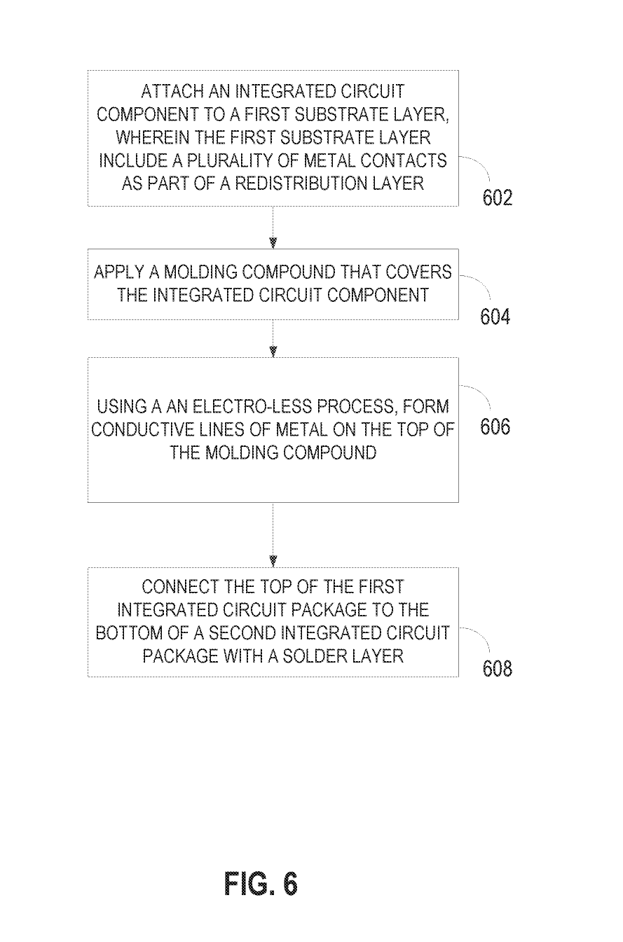

FIG. 6 shows a flow diagram of a method of creating a package-on-package device using a laser assisted self-activating monolayer, in accordance with some example embodiments.

In some example embodiments, an integrated circuit component 530 is attached (602) to a first substrate layer, wherein the first substrate layer includes a plurality of metal contacts 520 as part of a redistribution layer. In some example embodiments, this attachment is made using solder. In other example embodiments, a surface mounting technique is used.

In some example embodiments, the solder layer is arranged as a ball grid array 534. In some example embodiments, the redistribution layer is composed of copper.

In some example embodiments, the redistribution layer includes at least one metal contact that is directly above a die component in the first semiconductor device package.

In some example embodiments, the first integrated circuit package 502 connects the redistribution layer to metal contacts 508 on the substrate using a through mold via.

In some example embodiments, the first integrated circuit package 502 connects the redistribution layer to metal contacts 508 on the substrate using wire bonds.

In some example embodiments, a molding compound 512 that covers the integrated circuit component 530 is applied (604) to the substrate.

In some example embodiments, conductive lines of metal are formed (606) on the top of the molding compound 526 using an electrolysis process.

In some example embodiments, conductive lines of metal on the top of molding compound 526 are formed using a process that further comprises activating a predetermined pattern on the top of a molding 106 using a pulsed-wave ultraviolet laser.

Once the laser has activated a predetermined pattern in the molding 106, hydrolysis is used to create an OH rich area based on the predetermined pattern activated by the pulsed-wave ultraviolet laser. A self-assembling monolayer including a functional group is grafted onto the OH rich area of the molding compound 526 though condensation.

In some example embodiments, a palladium catalyst is activated only on the area of the molding 106 onto which the self-assembling monolayer was grafted.

A metal later is deposited on the palladium activated area using an electrolysis process. In some example embodiments, the metal layer is copper. In other example embodiments, another suitable conductive metal can be used.

In some example embodiments, the top of the first integrated circuit package 502 is connected (608) to the bottom of a second integrated circuit package 504 with a solder layer.

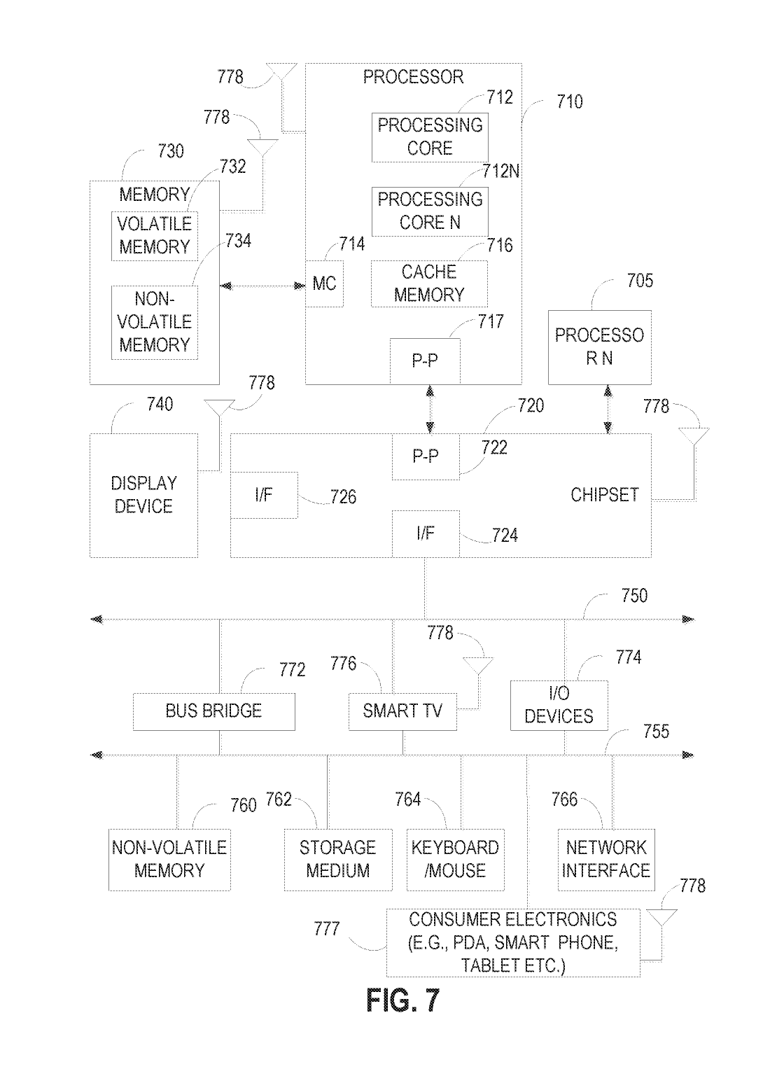

FIG. 7 illustrates a system level diagram, according to one example embodiment. For instance, FIG. 7 depicts an example of an electronic device (e.g., system) including a multi-die IC package with an interconnect bridge embedded in the substrate 104 as described in the present disclosure. FIG. 7 is included to show an example of a higher level device application. In one embodiment, the system includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 700 is a system on a chip (SOC) system.

In one embodiment, processor 710 has one or more processing cores 712 and 712N, where 712N represents the Nth processor core inside processor 710 where N is a positive integer. In one embodiment, system 700 includes multiple processors including 710 and 705, where processor 705 has logic similar or identical to the logic of processor 710. In some embodiments, processing core 712 includes, but is not limited to, pre-fetch logic to fetch instructions, decode logic to decode the instructions, execution logic to execute instructions, and the like. In some embodiments, processor 710 has a cache memory 716 to cache instructions and/or data for system 700. Cache memory 716 may be organized into a hierarchal structure including one or more levels of cache memory 716.

In some embodiments, processor 710 includes a memory controller 714, which is operable to perform functions that enable the processor 710 to access and communicate with memory 730 that includes a volatile memory 732 and/or a non-volatile memory 734. In some embodiments, processor 710 is coupled with memory 730 and chipset 720. Processor 710 may also be coupled to a wireless antenna 778 to communicate with any device configured to transmit and/or receive wireless signals. In one embodiment, the wireless antenna interface 778 operates in accordance with, but is not limited to, the IEEE 802.11 standard and its related family, Home Plug AV (HPAV), Ultra-Wide Band (UVB), Bluetooth, WiMax, or any form of wireless communication protocol.

In some embodiments, volatile memory 732 includes, but is not limited to, synchronous dynamic random access memory (SDRAM), dynamic random access memory (DRAM), RAMBUS dynamic random access memory (RDRAM), and/or any other type of random access memory device. Non-volatile memory 734 includes, but is not limited to, flash memory, phase change memory (PCM), read-only memory (ROM), electrically erasable programmable read-only memory (EEPROM), or any other type of non-volatile memory device.

Memory 730 stores information and instructions to be executed by processor 710. In one embodiment, memory 730 may also store temporary variables or other intermediate information while processor 710 is executing instructions. In the illustrated embodiment, chipset 720 connects with processor 710 via Point-to-Point (PtP or P-P) interfaces 717 and 722. Chipset 720 enables processor 710 to connect to other elements in system 700. In some embodiments, interfaces 717 and 722 operate in accordance with a PtP communication protocol such as the Intel® QuickPath Interconnect (QPI) or the like. In other embodiments, a different interconnect may be used.

In some embodiments, chipset 720 is operable to communicate with processor 710, 705, display device 740, and other devices 772, 776, 774, 760, 762, 764, 766, 777, and so forth. Chipset 720 may also be coupled to a wireless antenna 778 to communicate with any device configured to transmit and/or receive wireless signals.

Chipset 720 connects to display device 740 via interface 726. Display device 740 may be, for example, a liquid crystal display (LCD), a plasma display, cathode ray tube (CRT) display, or any other form of visual display device. In some embodiments, processor 710 and chipset 720 are merged into a single SOC. In addition, chipset 720 connects to one or more buses 750 and 755 that interconnect various elements 774, 760, 762, 764, and 766. Buses 750 and 755 may be interconnected together via a bus bridge 772. In one embodiment, chipset 720 couples with a non-volatile memory 760, mass storage device(s) 762, keyboard/mouse 764, and network interface 766 via interface 724 and/or 704, smart TV 776, consumer electronics 777, and so forth.

In one embodiment, mass storage device 762 includes, but is not limited to, a solid state drive, a hard disk drive, a universal serial bus flash memory drive, or any other form of computer data storage medium. In one embodiment, network interface 766 is implemented by any type of well-known network interface standard including, but not limited to, an Ethernet interface, a universal serial bus (USB) interface, a peripheral component interconnect (PCI) Express interface, a wireless interface and/or any other suitable type of interface. In one embodiment, the wireless interface operates in accordance with, but is not limited to, the IEEE 802.11 standard and its related family, HPAV, UWB, Bluetooth, WiMax, or any form of wireless communication protocol.

While the modules shown in FIG. 7 are depicted as separate blocks within the system 700, the functions performed by some of these blocks may be integrated within a single semiconductor circuit or may be implemented using two or more separate integrated circuits. For example, although cache memory 716 is depicted as a separate block within processor 710, cache memory 716 (or selected aspects of 716) can be incorporated into processor core 712.

### Additional Notes and Examples

Example 1 is a high density package on package electrical device, comprising a first integrated circuit package comprising a substrate, an integrated circuit component attached to the substrate, and a molding compound covering the integrated circuit component, wherein the top of the molding compound has a redistribution layer of metal covering at least part of the molding compound; a second integrated circuit package including a second substrate, an semiconductor component attached to the substrate, and a molding compound covering the electronic component, and wherein the bottom of the substrate includes metal contacts for communication between the second integrated circuit package and other components; and a solder layer that connects the top of the first integrated circuit package to the bottom of the second electric package by connecting the metal of the redistribution layer to the metal connections on the bottom of the second substrate.

In Example 2, the subject matter of Example 1 optionally includes the solder layer is arranged as a ball grid array.

In Example 3, the subject matter of Example 1 optionally includes wherein the redistribution layer is composed of copper.

In Example 4 the subject matter of Example 1 optionally includes wherein the first integrated circuit package connects the redistribution layer to metal contacts on the substrate using a through mold via.

In Example 5, the subject matter of Example 4 optionally includes instructions to, for the particular potential transcription: construct a syntactic parse tree for the particular potential transcription, based at least in part on part of speech tags associated with the plurality of words in the particular potential transcription.

In Example 6, the subject matter of Example 1 optionally includes wherein the first integrated circuit package connects the redistribution layer to metal contacts on the substrate using wire bonding.

In Example 7 the subject matter of Example 1 optionally includes wherein the mold compound in the first integrated circuit package is composed with a filler size that is significantly smaller than the size of a pattern feature.

In Example 8 the subject matter of Example 1 optionally includes wherein the first integrated circuit package further includes peripheral metal contacts that connect to the substrate by through mold via interconnects between the peripheral metal contacts on top of the mold compound and substrate circuits.

Example 9 is a method for creating a high density package on package device through self-assembling monolayers, the method comprising attaching an integrated circuit component to a first substrate layer, wherein the first substrate layer includes a plurality of metal contacts as part of a redistribution layer; applying a molding compound that covers the integrated circuit component; using an electrolysis process, forming conductive lines of metal in a redistribution layer on the top of the molding compound; and connecting the top of a first integrated circuit package to the bottom of a second integrated circuit package with a solder layer.

In Example TO, the subject matter of Example 9 optionally includes wherein the solder layer is arranged as a ball grid array.

In Example 11, the subject matter of Example 9 optionally includes wherein the redistribution layer is composed of copper.

In Example 12, the subject matter of Example 9 optionally include wherein the redistribution layer includes at least one metal contact that is directly above a die component in the first semiconductor device package.

In Example 13, the subject matter of Example 9 optionally includes wherein forming conductive lines of metal on the top of the molding compound further comprises activating a predetermined pattern on the top of a molding using a pulsed-wave ultraviolet laser.

In Example 14, the subject matter of Example 13 optionally includes using hydrolysis, by immersing the mold compound in water, to create an rich bond based on the predetermined pattern activated by the pulsed-wave ultraviolet laser.

In Example 15, the subject matter of Example 14 optionally include grafting a self-assembling monolayer, including a functional group, onto the OH rich area of the molding compound though condensation.

In Example 16, the subject matter of Example 15 optionally includes activating a palladium catalyst only on the area of the molding onto which the self-assembling monolayer was grafted.

In Example 17, the subject matter of Example 16 optionally include depositing a metal layer on the palladium activated area using an electrolysis process.

Example 18 is a high density package on package electrical device, comprising a first integrated circuit package comprising a substrate, an integrated circuit component attached to the substrate, and a molding compound covering the electronic component, wherein the top of the molding compound has a redistribution layer of metal covering at least part of the molding compound and a wire bond connects metal contacts on the substrate to the redistribution layer; a second integrated circuit package including a substrate, a semiconductor component attached to the substrate, and a molding compound covering the electronic component, and wherein the bottom of the substrate includes metal contacts for communication between the second integrated circuit package and other components; and a solder layer that connects the top of the first integrated circuit package to the bottom of the second integrated circuit package by connecting the metal of the redistribution layer to the metal connections on the bottom of the second substrate.

In Example 19, the subject matter of Example 18 optionally includes wherein the solder layer is arranged as a ball grid array.

In Example 20, the subject matter of Example 18 optionally includes wherein the redistribution layer is composed of copper.

Example 21 is at least one computer-readable medium comprising instructions to perform any of the methods of Examples 9-17.

Example 22 is an apparatus comprising means for performing any of the methods of Examples 9-17.

Example 23 is apparatus for creating a high density package on package device through self-assembling monolayers, the apparatus comprising means for attaching an integrated circuit component to a first substrate layer, wherein the first substrate layer includes a plurality of metal contacts as part of a redistribution layer; means for applying a molding compound that covers the integrated circuit component; means for, using an electrolysis process, forming conductive lines of metal in a redistribution layer on the top of the molding compound; and means for connecting the top of a first integrated circuit package to the bottom of a second integrated circuit package with a solder layer.

In Example 24, the subject matter of Example 23 optionally includes wherein the solder layer is arranged as a ball grid array.

In Example 25, the subject matter of Example 23 optionally includes wherein the redistribution layer is composed of copper.

In Example 26; the subject matter of Example 23 optionally includes wherein the redistribution layer includes at least one metal contact that is directly above a die component in the first semiconductor device package.

In Example 27, the subject matter of Example 23 optionally includes wherein means for forming conductive lines of metal on the top of the molding compound further comprise: means for activating a predetermined pattern on the top of a molding using a pulsed-wave ultraviolet laser.

In Example 28, the subject matter of Example 27 optionally includes means for, using hydrolysis, by immersing the mold compound in water, to create an rich bond based on the predetermined pattern activated by the pulsed-wave ultraviolet laser.

In Example 29, the subject matter of Example 28 optionally includes means for grafting a self-assembling monolayer, including a functional group, onto the OH rich area of the molding compound though condensation.

In Example 30, the subject matter of Example 29 optionally includes means for activating a palladium catalyst only on the area of the molding onto which the self-assembling monolayer was grafted.

In Example 31, the subject matter of Example 30 optionally includes means for depositing a metal layer on the palladium activated area using an electrolysis process.

### Term Usage

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

1. A high density package on package electrical device, comprising:
a first integrated circuit package comprising a substrate, an integrated circuit component attached to the substrate, and a molding compound covering the integrated circuit component, wherein the top of the molding compound has a redistribution layer of metal covering at least part of the molding compound; and
a second integrated circuit package including a second substrate, an semiconductor component attached to the substrate, and a molding compound covering the electronic component, and wherein the bottom of the substrate includes metal contacts for communication between the second integrated circuit package and other components.

2. The electronic device of claim 1, further comprising a solder layer that connects the top of the first integrated circuit package to the bottom of the second electric package by connecting the metal of the redistribution layer to the metal connections on the bottom of the second substrate.

3. The electronic device of claim 2, wherein the solder layer is arranged as a ball grid array.

4. The electrical device of claim 1, wherein the redistribution layer is composed of copper.

5. The electronic device of claim 1, wherein the redistribution layer includes at least one metal contact that is directly above a die component in the first semiconductor device package.

6. The electronic device of claim 1, wherein the first integrated circuit package connects the redistribution layer to metal contacts on the substrate using a through mold via.

7. The electronic device of claim 1, wherein the first integrated circuit package connects the redistribution layer to metal contacts on the substrate using wire bonding.

8. The electronic device of claim 1, wherein the mold compound in the first integrated circuit package is composed with a filler size that is smaller than the size of a pattern feature.

9. The electronic device of claim 1, wherein the first integrated circuit package further includes peripheral metal contacts that connect to the substrate by through mold via interconnects between the peripheral metal contacts on top of the mold compound and substrate circuits.

10. A method for creating a high density package on package device through self-assembling monolayers, comprising:
attaching an integrated circuit component to a first substrate layer, wherein the first substrate layer includes a plurality of metal contacts;
applying a molding compound that covers the integrated circuit component;
forming conductive lines of metal in a redistribution layer on the top of the molding compound; and
connecting the top of a first integrated circuit package to the bottom of a second integrated circuit package with a solder layer.

11. The method of claim 10, wherein the redistribution layer includes at least one metal contact that is directly above a die component in the first semiconductor device package.

12. The method of claim 10, wherein forming conductive lines of metal on the top of the molding compound further comprises:
activating a predetermined pattern on the top of a molding using a pulsed-wave ultraviolet laser.

13. The method of claim 12, wherein forming conductive lines of metal in a redistribution layer on the top of the molding compound further comprises:
using hydrolysis, by immersing the mold compound in water, to create an OH rich bond based on the predetermined pattern activated by the pulsed-wave ultraviolet laser.

14. The method of claim 14, further comprising:
grafting a self-assembling monolayer, including a functional group, onto the OH rich area of the molding compound though condensation.

15. The method of claim 14, further comprising.
activating a palladium catalyst only on the area of the molding onto which the self-assembling monolayer was grafted.

16. The method of claim 15, further comprising:
depositing a metal layer on the palladium activated area using an electrolysis process.

17. A high density package on package electrical device, comprising:
a first integrated circuit package comprising a substrate, an integrated circuit component attached to the substrate, and a molding compound covering the electronic component, wherein the top of the molding compound has a redistribution layer of metal covering at least part of the molding compound and a wire bond connects metal contacts on the substrate to the redistribution layer; and
a second integrated circuit package including a substrate, a semiconductor component attached to the substrate, and a molding compound covering the electronic component, and wherein the bottom of the substrate includes metal contacts for communication between the second integrated circuit package and other components.

18. The high dens package on package electrical device of claim 17, further comprising:
a solder layer that connects the top of the first integrated circuit package to the bottom of the second integrated circuit package by connecting the metal of the redistribution layer to the metal connections on the bottom of the second substrate.

19. The electronic device of claim 18, wherein the solder layer is arranged as a ball grid array.

20. The electrical device of claim 17, wherein the redistribution layer is composed of copper.
